(19) United States
(12) Patent Application Publication
(10) Pub. No.: US 2009/0325362 A1
(43) Pub. Date: Dec. 31, 2009

(54) METHOD OF RECYCLING AN EPITAXIED DONOR WAFER

(76) Inventors: Nabil Chhaimi, Echirolles (FR); Eric Guiot, Goncelin (FR); Patrick Reynaud, Saint Martin D'Heres (FR); Bruno Ghyselen, Seyssinet-Pariset (FR); Cécile Aulnette, Guilderland, NY (US); Bénédicte Osternaud, St Laurent du Pont (FR); Takeshi Akatsu, Tokyo (JP); Bruce Faure, Paris (FR)

Correspondence Address: WINSTON & STRAWN LLP;PATENT DEPARTMENT, 1700 K STREET, N.W., WASHINGTON, DC, 20006, US

(21) Appl. No.: 12/503,537

(22) Filed: Jul. 15, 2009

Related U.S. Application Data
(63) Continuation-in-part of application No. 11/386,967, filed on Mar. 21, 2006.
Application No. 11/386,967 is a continuation-in-part of application No. 11/075,323, filed on Mar. 7, 2005, now Pat. No. 7,602,046.
Application No. 11/075,323 is a continuation of application No. PCT/IB2004/000285, filed on Jan. 7, 2004.
(60) Provisional application No. 60/472,470, filed on May 22, 2003.

(30) Foreign Application Priority Data
Jan. 7, 2003 (FR) 0300098
Oct. 18, 2005 (FR) 0510596

(51) Int. Cl. H01L 21/762

(52) U.S. Cl. 438/455; 438/692; 438/478; 438/458; 257/E21.567

(57) ABSTRACT

A method for forming a semiconductor structure that includes a thin layer of semiconductor material on a receiver wafer is disclosed. The method includes removing a thickness of material from a donor wafer, which comprises a support substrate and an epitaxial layer, for surface preparation and transferring a portion of the epitaxial layer from the donor wafer to the receiver wafer. The thickness removed during the surface preparation is adapted to enable formation of a new semiconductor structure from the remaining epitaxial portion of the donor wafer.

### CROSS-REFERENCE TO RELATED APPLICATIONS

This application is a continuation-in-part of application Ser. No. 11/386,967 filed Mar. 21, 2006, a continuation-in-part of each of application Ser. Nos. 11/075,272 and 11/075,323, each filed Mar. 7, 2005, each of which in turn is a continuation of International Application PCT/IB2004/000285 filed Jan. 7, 2004 and claims the benefit of provisional application 60/472,470 filed May 22, 2003. The entire content of each cited application is expressly incorporated herein by reference thereto.

### FIELD OF THE INVENTION

The present invention relates to a process of manufacturing a semiconductor structure. More particularly, the invention relates to recycling a donor wafer used in the manufacturing process.

### BACKGROUND OF THE INVENTION

A “semiconductor-on-insulator” (“SeOI”) type substrate is known, and is widely used in various fields, especially in the fields of optics, electronics, and optoelectronics. SeOI structures are generally fabricated by: depositing a thin, semiconductor layer on a support substrate by epitaxial growth to form a “donor” wafer; implanting atomic species within the donor substrate using a method known commercially as SMART-CUT® to form a zone of weakness therein; bonding a “receiver” substrate onto the free surface of the epitaxial layer; and detaching along the zone of weakness to form the SeOI structure and a negative, which is the donor substrate and the remaining portion of the thin layer.

After removing the thin layer from the donor wafer, the negative is typically not recycled, and it is therefore necessary to use a new support substrate and form a new donor wafer when producing another semiconductor-receiver wafer structure. Thus, the long, complex, and expensive operation of epitaxial growth must be repeated every time a new structure is produced.

To address this disadvantage, a technique for recycling the donor wafer has been proposed. U.S. Patent Publication No. US 2004/0152284 is directed to recycling a donor wafer where the epitaxied structure comprises a stack of SiGe layers epitaxied on an Si substrate. According to this publication, a specific layer, namely, a stop layer which acts as a barrier for material attack, is placed in the stack of layers. The presence of this stop layer allows selective removal of the material, e.g., by selective chemical etching, during recycling. With reference to FIGS. 7a-7f of US 2004/0152284, the stop layer 3 is used for selective removal of the remaining part 7 after removing the epitaxied structure 1. After the selective removal, a specific epitaxy operation is performed to reform a structure similar to the originally epitaxied structure (epitaxy of layer 4′) and to create a wafer that can act as a donor wafer.

However, the method disclosed in US 2004/0152284 presents a number of disadvantages. It requires that a specific epitaxy be performed to form the stop layer. It also requires a selective material removal step as well as an additional epitaxy step to reform the epitaxied structure from which the thin layer is produced. Unfortunately, the cost of an epitaxy step is relatively high, especially because of its relatively long process time and the special equipments and gases required during the process. Hence, there is a need for a simple and inexpensive technique for recycling a negative.

The present invention addresses this need by providing a recycling technique which is simple and inexpensive, and which can advantageously be integrated in an SeOI structure manufacturing process using a SMART-CUT®-type technology.

### SUMMARY OF THE INVENTION

The present invention provides a method for producing two or more semiconductor structures using a single donor wafer because the donor wafer used in the process is recycled.

The method comprises providing a donor wafer comprising a support substrate, and a hetero-epitaxial layer comprising a buffer layer having a mesh parameter that is different from that of the support substrate, and at least one epitaxial layer of semiconductor material on the buffer layer; transferring a portion of the at least one epitaxial layer to a receiver wafer to form a first semiconductor structure which comprises the receiver wafer and a semiconductor layer of the at least one epitaxial layer portion on the receiver wafer and second semiconductor structure which comprises the support substrate, the buffer layer and the remaining, non-transferred portion of the epitaxial layer; treating the second semiconductor structure by removing at least part of the remaining, non-transferred portion of the epitaxial layer without removing the buffer layer to form a treated semiconductor structure having a surface that is sufficiently smooth for growth of at least one further epitaxial layer thereon; and recycling the treated semiconductor structure for transfer of a portion of the further epitaxial layer.

The portion of the epitaxial layer is removed non-selectively, such as by chemical-mechanical polishing. Typically, the portion of the epitaxial layer removed is a thickness of between about 0.1 and 4 μm, preferably by a chemical-mechanical polishing with a polishing pad having a compressibility of about 2 to 15% and a slurry containing about 20% or more of silica particles having a size of about 70 to 210 nm. A preferred thickness of epitaxial layer to be removed is between about 0.1 and 2 μm.

The second semiconductor structure often includes a flange on an edge of the non-transferred portion of the epitaxial layer, the flange corresponding to a periphery of the transferred epitaxial portion, and the removing step advantageously includes eliminating the flange. The flange may be eliminated by polishing or by local plasma etching. If desired, the method can include providing an additional epitaxial layer on the treated semiconductor structure prior to recycling.

The transfer of the epitaxial layer can be effected by forming a weakened zone within the at least one epitaxial layer; bringing the donor wafer and the receiver wafer into intimate contact; and detaching the donor and the receiver wafers at the weakened zone to effect transfer of a portion of the at least one epitaxial layer from the donor wafer to the receiving substrate. The second semiconductor structure formed after the detachment includes the flange and can be treated with a degassing heat treatment, for example an annealing at a temperature greater than 700° C. to remove the flange. After the degassing heat treatment, the surface of the structure can be cleaned, e.g., with an RCA type cleaning. An oxide layer can be formed on the surface of the structure after the cleaning and then eliminated, e.g., by chemical etching, to smooth the surface.

According to one example, the support substrate is an Si substrate and the epitaxial layer comprises a relaxed SiGe layer on an SiGe buffer layer, which is formed by epitaxial growth on the support substrate and has a progressively increasing Ge content from the interface with the support substrate. An overlayer of strained Si or a first layer of relaxed SiGe and a second layer of strained Si can be further provided on the epitaxial layer. The overlayer can have a mesh parameter that is essentially the same as that of the adjacent epitaxial layer. If desired, an oxide layer of e.g., silicon oxide can be provided on the epitaxial layer prior to bringing the donor wafer and receiving substrate into contact.

### BRIEF DESCRIPTION OF THE DRAWINGS

The present invention will be further described in the following description with references to the drawings in which:

FIG. 1 graphically illustrates the steps of transferring an epitaxial layer from a donor wafer to a receiver wafer according to an embodiment of the invention; and

FIG. 2 graphically illustrates typical configurations of a semiconductor structure and the transfer of an epitaxial layer according to an embodiment of the invention.

### DETAILED DESCRIPTION OF THE PREFERRED EMBODIMENTS

The present invention relates to formation of a structure comprising an epitaxial layer of semiconductor material on a receiver wafer, where the epitaxial layer has been transferred to the receiver wafer from a donor wafer, and to the recycling of the donor wafer after transfer of the epitaxial layer.

The invention enables recycling of a donor wafer, which includes, before the transfer, a support substrate on which a layer is formed by epitaxial growth. A part of this epitaxial layer is transferred onto a receiver wafer. After the transfer, the donor wafer comprises the support substrate and the remaining, unremoved part of the epitaxial layer.

The donor wafer to be recycled is typically a negative which results from the transfer process during in which the donor wafer is brought in contact with a receiver wafer and then detached at a weakened or embrittlement zone created within the thickness of the epitaxied layer, for example by implantation of atomic or ionic species. Detachment is achieved by application of thermal stress, possibly in combination with mechanical stress (as in the SMART-CUT® process), by application of mechanical stress alone (e.g., an ELTRAN® process, which uses a pressurized fluid jet at a porous weakened layer), or by any other suitable means (e.g., ultrasound).

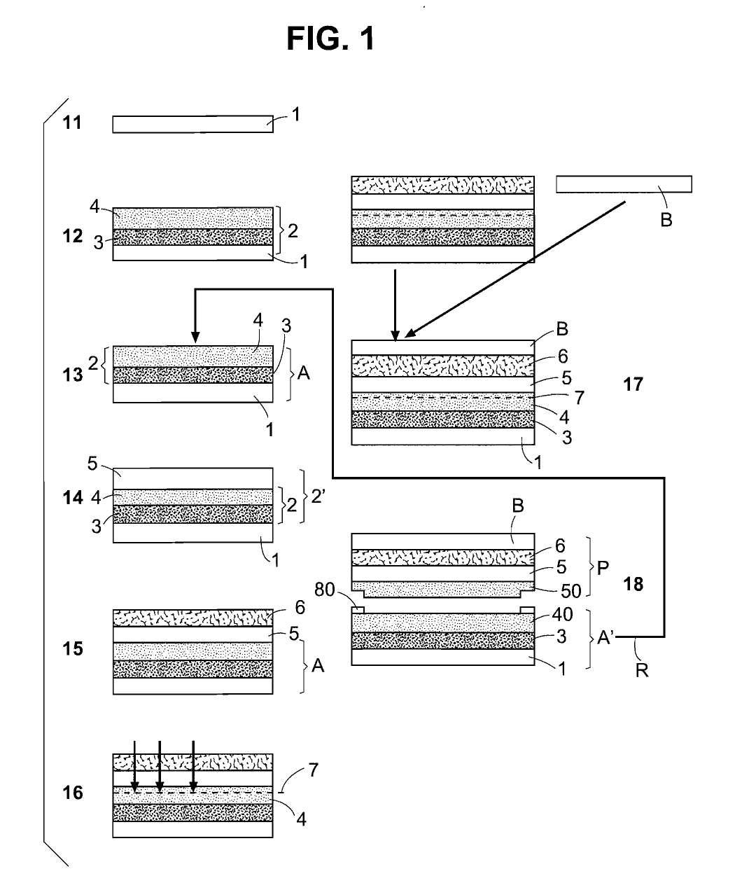

The main steps of the transfer method according to an embodiment of the invention, wherein detachment is provided at a level within the embrittlement zone, are illustrated in FIG. 1. This figure shows a series of steps 11 to 18 for manufacturing an SeOI type structure and for producing a remainder or negative A′, which originates from the donor wafer A.

Starting from step 11, in which a support substrate 1 (e.g., a silicon substrate) is provided, a structure 2 comprising a layer or superposition of layers is formed on the support substrate in step 12 by epitaxial growth. In the particular example shown in FIG. 1, the epitaxial structure 2 comprises a buffer layer 3 and a layer 4 on the buffer layer 3. This type of structure is known as a “hetero-epitaxial” structure. While the structure 2 is often referred as an epitaxial layer, it will be appreciated that the structure is not limited to a single layer but can include more than one layer, as shown in FIG. 1.

The buffer layer 3 provided on the support substrate 1 has a mesh parameter on its surface that is significantly different from the mesh parameter of the support substrate 1. For example, the buffer layer can be a SiGe layer, with a Ge concentration progressively increasing from the interface with the Si support substrate and consequently having a mesh parameter that is progressively modified to set up the transition between the two mesh parameters. Such progressive modification of the mesh parameter can be achieved gradually within the thickness of the buffer layer. Alternatively, it can be achieved in “stages,” with each stage being a thin layer with a substantially constant mesh parameter different from the mesh parameter of the subjacent stage, so that the mesh parameter is discretely modified stage by stage. The general composition of these stages can be defined as SiₓGe₁₋ₓ where 0≦x≦1 with x in each stage being different.

The layer 4 is located on the buffer layer 3 and has the mesh parameter of the buffer layer surface, different from the mesh parameter of the support substrate. The layer 4 is typically made of a material relaxed by the buffer layer 3, for example relaxed SiGe. In certain situations, layer 4 can also be Ge; SiGe and Ge; GaAs and Ge; an alloy belonging to Group III-V; GaAs, InP; InGaAs; AlN, InN, or GaN. The buffer layer to be used is one that is compatible with layer 4, for example, when layer 4 is a nitride layer, the buffer layer is also a layer of nitride material.

The buffer layer 3 and the layer 4 are formed by epitaxial growth on the support substrate 1, using known techniques such as CVD (Chemical Vapor Deposition) and MBE (Molecular Beam Epitaxy) techniques. The layer 4 can be formed in situ, directly after the formation of the subjacent buffer layer 3, or can be formed after a finishing step is conducted on the buffer layer.

Steps 11 and 12 are thus used to form a donor wafer. This donor wafer is also described as a “fresh” wafer in the following description, since it does not originate from recycling.

The next step 13 is a surface preparation step for the epitaxial structure 2. In the example shown, the surface of the layer 4 is prepared, typically by removing material from the surface, for example by chemical mechanical polishing (CMP).

Step 14 is an optional step. In this step, an overlayer 5 is formed on the surface of the donor wafer A, i.e., on the surface of the layer 4 of relaxed SiGe by epitaxial growth. The formation of the overlayer 5 can be performed in the same way as the formation of the layer 4. Thus, a hetero-epitaxial structure 2′, including the buffer layer 3, the epitaxial layer 4, and the overlayer 5, is formed on the support substrate 1. Advantageously, the mesh parameter of the overlayer 5 is essentially the same as the mesh parameter of the relaxed material 4 on the free face of the structure 2. In the example shown, it is typically a strained Si layer on the surface of the relaxed SiGe layer 4. The overlayer 5 may also include a first layer of relaxed SiGe and a second layer of strained Si arranged on the first layer, by performing a SiGe epitaxy before the strained Si layer is deposited, also by epitaxy. One possible application of the donor wafer A is to take off a thin layer from a part of the layer 4 of the epitaxied structure 2 on the support substrate 1, or from the optional overlayer 5 formed on the surface of the structure 2.

An optional step can be performed in step 15, to form an oxide layer 6 on the surface of the donor wafer and/or the receiver wafer. This step would depend on the final product to be obtained; in the example shown in FIG. 1, the final product is an SeOI structure including an insulation layer corresponding to the oxide layer.

In step 16, atomic species, such as hydrogen and/or helium ions, are implanted in the donor wafer to form a weakened or embrittlement zone 7 within the thickness of the epitaxied structure 2, 2′, e.g., within the thickness of the layer 4 as shown in FIG. 1. As noted above, in an alternative embodiment this zone can be formed in overlayer 5.

In the next step 17, the oxidized donor wafer A is bonded to the receiver wafer B. “Bonding” means creating an intimate and permanent contact that may correspond to molecular bonding and that may also be reinforced by adding a material or product between the interface surfaces of the oxidized donor wafer and the receiver wafer to facilitate bonding. Bonding is generally preceded by cleaning the surfaces to be bonded.

In step 18, the assembly thus formed by bonding is detached at embrittlement zone 7, by applying thermal and/or mechanical stress. The result of this step is a positive structure P and a negative structure A′.

The positive structure P is an SeOI structure in which the surface layer corresponds to the layer of the donor wafer A that is defined by the embrittlement zone and that includes part 50 of the layer 4 and if present the overlayer 5 formed in optional step 14. This structure includes the transferred part that corresponds to the part of the structure 2 (or 2′) having a free surface defined by the embrittlement zone and the layers that are brought into contact with the receiver wafer B.

It is also possible to form layer 4 with sufficient thickness to provide (a) at least two useful layers for detachment therefrom and (b) additional material for removal to planarize exposed surfaces of the useful layers to sequentially prepare each layer for molecular bonding to a separate receiving substrate. After the removal of part of layer 4, a second implanting can be conducted to make a second embrittlement zone which then allows detachment of the second portion of layer 4 onto the second receiving substrate. The original thickness of layer 4 allows the first portion of that layer to be molecularly bonded to a first receiving substrate and then to allow the selective removal and transfer of a first useful layer thereto, while a portion of layer 4 as a second useful layer remains intact. The thickness of layer 4 is also sufficient to allow the remaining portion of the formed layer to be subsequently bonded to a second receiving substrate to allow the selective removal and transfer of the second useful layer thereto without reforming the remaining portion of the layer 4.

Thus, when steps 14 and 15 are performed, the positive structure P comprises the receiver wafer B, on which the oxide layer 6, the strained silicon overlayer 5, and the transferred part 50 of the relaxed SiGe layer 4 are stacked in sequence. The transferred part 50 is then typically removed so that the end result is an sSOI (Strained Silicon On Insulator) type structure.

When step 14 is not performed, the result is a positive structure comprising the receiver wafer B on which the oxide layer 6 (if included) and the transferred part 50 of the relaxed SiGe layer 4 are stacked in sequence. The next step is typically a deposit by epitaxial growth of a silicon layer on layer 50 (acting as a growth substrate), and the silicon in the deposited layer is then strained by the relaxed SiGe in the subjacent layer 50. The end result is an SGOI (Strained silicon on SiGe On Insulator) type structure.

The negative A′ corresponds to the part of the donor wafer that did not remain bonded to the receiver wafer B, and comprises the support substrate 1 and the remaining non-transferred part 40 of the epitaxied structure 2, 2′. The remaining part 40 corresponds to the part of the layer 4 that did not remain bonded to the receiver wafer B because it was subjacent to the embrittlement zone 7 where the detachment was made.

The invention includes a method for forming a structure comprising a thin layer of a semiconductor material on a receiver wafer, the method comprising the steps of: (i) surface preparation by removing a thickness of material from a donor wafer comprising a support substrate on which at least one layer is formed by epitaxial growth; and (ii) transfer of part of the epitaxial layer from the donor wafer to the receiver wafer to form an epitaxial layer on the receiver wafer, wherein the transfer forms a negative which includes the support substrate and the remaining non-transferred part of the epitaxial layer. The method is characterized in that the thickness removed by the surface preparation step is adapted such that application of the surface preparation step to the negative enables formation of a new thin layer from the remaining part in which the thickness has been reduced by the surface preparation step.

The following are some of the non-limiting features and benefits of the present method:
material can be removed non-selectively;
material can be removed by polishing, for example CMP type polishing;
the thickness removed can be adjusted as desired, e.g., between 0.1 and 4 μm or between 0.1 and 2 μm as typically used;
before the surface preparation step of a negative, a step can be performed on the negative to eliminate at least a part of a flange on the negative corresponding to the peripheral part of the transferred epitaxial layer that is not transferred to the receiver wafer but remains on the negative; because a wafer is typically disk-shaped, the flange forms a ring shape around the periphery of the negative when viewed from the top, and therefore is also referred as a “ring”;
the ring can be eliminated by polishing the edges of the negative;
the ring can be eliminated by locally removing material from the negative, for example by local plasma etching;
after the negative is formed, degassing heat treatment can be performed to burst or eliminate any micro-cavities formed in the negative;
the degassing heat treatment is an annealing carried out with a greater thermal budget, e.g., a temperature of more than 700° C., than that used in the heat treatment during detachment;
the surface of the negative is cleaned after the degassing heat treatment, for example by RCA type cleaning;
the oxide layer can be eliminated after cleaning by, e.g., HF type chemical etching;
when the epitaxied layer is a relaxed SiGe layer formed by epitaxial growth on an SiGe buffer layer, and the buffer layer is formed by epitaxial growth on an Si support substrate and has a Ge content that increases progressively from the interface with the support substrate, such that the transferred epitaxial layer includes part of the relaxed SiGe layer, a CMP polishing operation can be performed during surface preparation on the negative; during this surface preparation, the surface of the remaining non-removed part of the relaxed SiGe layer is polished, for example using a polishing pad, with a compressibility of between 2 and 15% and a slurry containing not less than 20% of silica particles with a size of between 70 and 210 nm;
when the epitaxied layer is made of relaxed SiGe, an overlayer can be formed by epitaxial growth after the surface preparation step; the overlayer comprises a layer of strained Si on the upper layer made of relaxed SiGe.

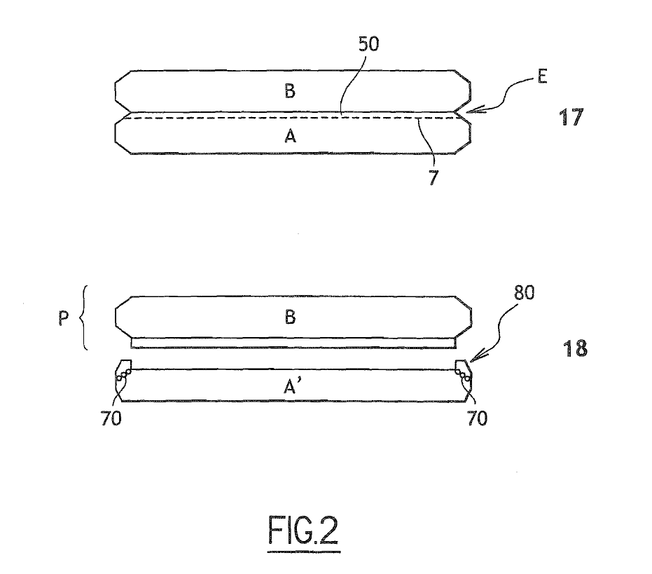

FIG. 2 shows how detachment takes place in step 18 after the bonding of step 17. The figure illustrates especially how a ring 80, a non-transferred zone, is formed at the surface of the negative A′.

In FIG. 2, which provides a more realistic wafer configuration than FIG. 1, the donor wafer A and the receiver wafer B are shown as having chamfered edges. In reality, edges of wafer elements are usually chamfered as shown in FIG. 2, rather than being sharp edged as in FIG. 1. This feature is standard for thin wafers of semiconductor materials, and limits exposure to damage that could result from a shock on unchamfered edges. A wafer typically has a chamfer at, for example, around 1.5 mm from the edge of the wafer, and the chamfer forms a peripheral annular zone around the wafer. It is noted that the chamfers in FIG. 2 are not shown in scale.

Thus, when the donor wafer A and the receiver wafer B are assembled, an annular notch E is formed at a peripheral region around the assembly. The notch E has a certain depth, e.g., a depth of about 1.5 mm.

Step 17 of FIG. 2 shows an embrittlement zone 7, created by implantation for example, which extends within the thickness of the donor wafer A at an approximately constant depth under the interface between the donor wafer A and the receiver wafer B. The weakened zone 7 extends from one edge of the wafer A to the opposite edge, and opens up at the notched region E.

Thus, not the entire surface of the layer 50 which is delimited by the embrittlement zone 7 is detached from the donor wafer. Instead, the detached part of the layer 50 corresponds only to the width of the layer 50 that was bonded to the receiver wafer B. The peripheral region outside this width remains on the donor wafer A and forms a ring 80 throughout the periphery of the wafer A. Because of the presence of the annular notch E, the ring 80 has a width comparable to the depth of the notch E. This ring 80 must be eliminated if the negative A′ is to be recycled. In addition, the surface condition must be improved in the central region of the negative where detachment occurs, since detachment generates surface disturbances.

Moreover, micro-cavities are created by the peripheral part 70 of the embrittlement zone 7, which remains within the thickness of the ring 80 during detachment. These micro-cavities are buried within the thickness of the ring, and must be eliminated, since they can expand or burst during thermal treatment of a recycling operation. Bursting of micro-cavities project particles under the surface of the negative, and impairs reusability of the negative. Since thermal treatments can be used throughout the SeOI structure manufacturing process, e.g., during oxide treatment (as in step 14) and detachment at a weakened zone (as in step 18), a negative should be able to withstand thermal treatment if it is to be reused.

Therefore, when recycling a negative, it is necessary to eliminate the ring 80; eliminate the peripheral part 70 of the embrittlement zone that remains buried in the negative; and improve the surface condition of the entire negative.

After the negative A′ is obtained, the negative A′ can be thermally treated to burst and eliminate micro-cavities at the edge of the negative (corresponding to the part 70 of the embrittlement zone). Such thermal treatment is also known as degassing heat treatment of the ring.

This thermal treatment can be an annealing stage with a sufficiently large thermal budget to eliminate all edge defects. This thermal budget is greater than those used during formation of a negative, e.g., during detachment of a negative from a donor wafer A by annealing. The thermal treatment used during formation of a negative is not sufficient to burst micro-cavities. Thus, for eliminating micro-cavities, annealing is performed at a temperature exceeding the annealing temperature for detachment. For example, the annealing can be performed at a temperature of more than 700° C. The annealing can be performed in a neutral or oxidizing atmosphere using, for example, argon, nitrogen, etc., or under a “smoothing” atmosphere, e.g., hydrogen-containing atmosphere, to reduce the surface roughness of the negative.

After the degassing heat treatment, the negative can be surface-cleaned, for example with RCA type cleaning. Typically, RCA cleaning treats the surface to be bonded with two solutions: a first bath of a solution known as “SC1” (Standard Clean 1), which includes a mix of ammonium hydroxide (NH₄OH), hydrogen peroxide (H₂O₂), and de-ionized water; and a second bath of a solution known as “SC2” (Standard Clean 2), which includes a mix of hydrochloric acid (HCl), hydrogen peroxide (H₂O₂), and de-ionised water. The first bath is used mainly to remove isolated particles present on the surface of the wafer and to make the surface hydrophilic, while the second bath is intended more specifically at removing metallic contamination.

After the cleaning, any oxide on the surface of the negative can be removed. Typically, the oxide covers only part of the surface of the negative, e.g., the ring and the back face. The entire surface of the negative may be covered with oxide, however, if a degassing heat treatment was performed under an oxidizing atmosphere. The oxide can be removed by chemical etching, e.g., by etching with HF. Such oxide removal is not necessary and can be omitted if the negative is derived from a donor wafer that was not oxidized.

According to an embodiment, a transfer method of the type shown in FIG. 1, i.e., a method in which a negative A′ is used as a donor wafer, is employed for the surface preparation step. Thus, the negative A′ is “inserted” in the transfer method at step 13 as if it were a “fresh” wafer. The arrow R shows this “insertion.” Such negative A′ is of the type formed after the detachment step 18 shown in FIG. 1. As described above, a degassing heat treatment was advantageously performed on this negative, either with or without the cleaning and de-oxidation steps, after it is formed and before it is used as a donor wafer in the surface preparation step. Thus, the surface preparation step is applied on the negative A′, i.e., on the remaining non-removed part 40 of the structure 2 (layer or superposition of layers) epitaxied on the support substrate 1.

The surface preparation reduces the thickness of the negative, but the thickness removed during the preparation is designed such that a new epitaxial layer can still be removed directly from the remaining part of the negative to form a new SeOI structure. In particular, a thickness sufficient to eliminate the ring and improve the surface condition of the remaining part of the epitaxied layer 4 is consumed.

The surface preparation performed on the negative is of the same type, and can employ the same equipment, as that performed on a fresh wafer. The present invention enables recycling of a donor wafer without requiring special equipment or techniques, but allows use of the existing manufacturing line and process that is already familiar to the manufacturer. Furthermore, no additional operation such as selective etching or epitaxy-type operation is required, since the negative can be prepared by simply adjusting the thickness removed using an existing technique. For example, where a thickness of about 20 nm is typically removed during surface preparation of a fresh donor wafer, a ring of a thickness of about 200 nm can be removed by adjusting the surface preparation operation to remove a greater thickness.

Therefore, it is now possible to reuse the negative A′ by directly reintegrating the negative in the standard process for transferring an epitaxial layer. The process reincorporates the negative A′ such that the negative is surface-prepared directly (step 13), without having to go through the extensive epitaxy of step 12. Furthermore, the surface preparation step according to the invention provides a means for directly making the surface condition of the remaining part compatible with removal of a new epitaxial layer. Disadvantages of the known recycling method, such as disadvantages related to selective removal of material by chemical etching, are eliminated.

According to one example, the surface of the negative A′ is polished to eliminate the ring 80. Thus, the remaining part 40 of layer 4 (see FIG. 1) is polished. Such polishing can also lower the roughness of the entire surface of the negative to a desired level to enable transfer of a new thin layer. Typically, roughness is reduced to less than 2 angstroms RMS in 10×10 μm² AFM.

Advantageously, because part 70 of the embrittlement zone 7 has been neutralized with degassing heat treatment to eliminate micro-cavities, this part 70 is unlikely to be subjected to problems that might occur during polishing. Had there been no prior heat treatment, problems can occur such as bursting during polishing or bursting of micro-cavities during a subsequent heat treatment. Elimination of the micro-cavities in the part 70 of the weakened zone also facilitates polishing of the ring, since such bursting weakens the ring and therefore facilitates its removal during polishing.

A thickness (Tr) is then removed from the remaining part 40 during the surface preparation. The thickness Tr can be adjusted to enable transfer of a new epitaxial layer having a thickness Ts from the remaining part. The minimum thickness to be removed depends on the thickness of the ring and the desired surface condition. The maximum thickness to be removed is such that the remaining part after surface preparation is thicker than the minimum thickness Tm required for transfer, e.g. 0.4 μm, below which it is no longer possible to transfer an epitaxial layer with a thickness Ts.

For example, a layer 4 having a thickness Ti between 1 and 50 μm on a fresh donor wafer A is considered. Subsequent to the implantation and detachment steps 16 and 17, the remaining part 40 of the layer 4 has a thickness Ti−Ts, where Ts represents the thickness of the removed epitaxial layer 50. After surface preparation of the negative, the thickness of the remaining part 40 is Ti−(Ts+Tr). Thus, in each recycling step, a thickness (Ts+Tr) is removed, resulting from removal of the thin layer (Ts) and removal of material during the ring elimination and surface preparation (Tr). It is thus possible to evaluate the number N of possible recycling operations according to the requirement Ti−N·(Ts+Tr)>Tm.

When the minimum thickness Tm is reached, after several recycling cycles, or even after a single recycling cycle, another deposition can be performed by epitaxial growth of layer 4, but without having to recreate the subjacent buffer layer 3, thereby saving time and cost of epitaxial growth described with reference to step 12 in FIG. 1. Such deposition can also be provided before the minimum thickness Tm is reached. For example, new deposition can be performed systematically after each time material is removed to produce a layer 4 with thickness Ti.

For manufacturing an sSoi structure, optional step 14 is performed to form an overlayer 5, for example, by providing an epitaxy of a first layer made of relaxed SiGe, followed by epitaxy of a strained Si layer arranged on the first layer. In this case, the first layer of relaxed SiGe is epitaxied after surface preparation of the negative and before making a new deposition of a strained Si layer.

With respect to surface preparation, polishing can be performed with a conventional polishing method, e.g., non-selective material removal, which uses a rotating polishing head a polishing plate. The polishing plate is free to rotate about a rotation axis, which can be parallel to the rotation axis of the head, and is covered with a polishing pad. The negative is inserted between the head and the plate, with the surface to be polished facing the pad and the fabric covering the plate. Polishing can also be used to remove material from a hetero-epitaxial structure, for example with polishing of the type described in International Application No. PCT/EP2004/006186. Typically, Chemical Mechanical Polishing (CMP) using a polishing pad with a compressibility of between 2 and 15% and an abrasive liquid (slurry) containing not less than 20% of silica particles with a size of between 70 and 210 nm is used.

In a preferred embodiment, when a negative is surface prepared, at least part of the ring is first eliminated before the surface preparation step. Advantageously, if at least part of the ring is eliminated in advance, less polishing will be required and less thickness can be removed. For example, where the thickness Tr, the thickness consumed during surface preparation of the remaining part 40 of the epitaxied structure, is about 0.1 to 4 μm when the ring is not eliminated in advance, this thickness Tr can be reduced to about 0.1 to 2 μm when the ring is eliminated in advance. Because it is usually difficult to perform polishing (e.g., CMP) at the periphery of the wafer (at the location of the ring), it is necessary to remove a greater thickness than the thickness of the ring when the ring is present. Thus, elimination of the ring prior to polishing enables removal of less thickness during surface preparation, and therefore allows for a greater number of recycling operations. Further, when the ring has been eliminated, the thickness removed during recycling can be closer to the thickness removed during a conventional surface preparation of a fresh wafer, and only a slight adjustment from the conventional method is required.

The ring can be eliminated by any suitable means. One method is the so-called “edge polish” technique, which is adapted to reduce the thickness of the ring by polishing the edges of the negative. This technique employs two different polishing plates inclined at an angle. Each plate is covered with a polishing pad, and a liquid abrasive is applied on the polishing pad. For example, an upper plate Ps, inclined by 15° from the surface of the negative, can be used with a lower plate Pi, which is inclined by 22°. By adjusting the angle, penetration into the wafer is adjusted. This edge polish technique also allows reconstitution of a chamfer around the edge of the wafer.

Another method is the local material removal technique, e.g., a DCP (Dry Chemical Polishing) type technique. For example, a local plasma etching can be performed by positioning a mask on the central part of the negative and applying a plasma etching (H₂ or O₂) to consume the thickness of the part of the negative not protected by the mask, i.e., the ring.

As an illustration, a layer 4 having an initial thickness Ti of 10 μm after the first surface preparation of a fresh wafer is considered. In a commercial product, Ti can typically be between about 1 and 50 μm, and Ts can be between 0.05 and 0.5 μm. A thin epitaxial layer with a thickness Ts of 0.2 μm is removed using a SMART-CUT® type transfer method. During recycling, the ring is eliminated, and a thickness Tr equal to 0.5 μm is removed from the remaining part 40 of the epitaxied structure in a non-selective, CMP type polishing. In this case, the number N of possible recycling operations is 13.

Therefore, the present invention provides a simple and inexpensive method of recycling the negative produced when a semiconductor structure is formed by transferring an epitaxied layer from a donor wafer to a receiver wafer. The present method is further advantageous in that it can be easily incorporated in an existing manufacturing process and can be adapted for any number of recycling as desired.

What is claimed is:

1. A method for producing two or more semiconductor structures using a single donor wafer, the method comprising the steps of:
providing a donor wafer comprising a support substrate, and a hetero-epitaxial layer comprising a buffer layer having a mesh parameter that is different from that of the support substrate,
treating the donor wafer by removing at least part of the hetero-epitaxial layer without removing the buffer layer to form a treated donor wafer having a surface that is sufficiently smooth for growth of at least one epitaxial layer thereon;
growing at least one epitaxial layer of semiconductor material on the hetero-epitaxial layer of the donor wafer;
transferring a portion of the at least one epitaxial layer to a receiver wafer to form a first semiconductor structure which comprises the receiver wafer and a semiconductor layer of the at least one epitaxial layer portion on the receiver wafer and a second semiconductor structure which comprises the support substrate, the buffer layer and the remaining, non-transferred portion of the epitaxial layer;
treating the second semiconductor structure by removing at least part of the remaining, non-transferred portion of the epitaxial layer without removing the buffer layer to form a treated semiconductor structure having a surface that is sufficiently smooth for growth of at least one further epitaxial layer thereon;
growing a further epitaxial layer on the treated semiconductor structure; and
recycling the treated semiconductor structure for transfer of a portion of the further epitaxial layer;
wherein the treating of the second semiconductor structure is conducted under the same conditions as the treating of the donor wafer to facilitate processing by not having to use different conditions.

2. The method according to claim 1, wherein the portion of the epitaxial layer is removed non-selectively.

3. The method according to claim 1, wherein the portion of the epitaxial layer is removed by chemical-mechanical polishing.

4. The method according to claim 3, wherein the portion of the epitaxial layer removed is a thickness of between about 0.1 and 4 μm.

5. The method according to claim 4, wherein the thickness of material is removed by a chemical-mechanical polishing with a polishing pad having a compressibility of about 2 to 15% and a slurry containing about 20% or more of silica particles having a size of about 70 to 210 nm so that the thickness removed from the epitaxial layer is between about 0.1 and 2 μm.

6. The method according to claim 1, wherein the second semiconductor structure includes a flange on an edge of the non-transferred portion of the epitaxial layer, the flange corresponding to a periphery of the transferred epitaxial portion, and wherein the flange is removed prior to the treating of the second semiconductor structure.

7. The method according to claim 6, wherein the flange is removed by polishing or by local plasma etching.

8. The method according to claim 1, wherein the transferring comprises providing at least one weakened zone within the at least one epitaxial layer; bringing the donor wafer and the receiver wafer into intimate contact; and detaching the donor and the receiver wafers at the weakened zone to effect transfer of the at least one epitaxial layer portion from the donor wafer to the receiving substrate, and optionally including a second weakened zone within the remaining portion of the at least one epitaxial layer for transfer of a second portion of that layer to another receiving substrate.

9. The method according to claim 8, wherein the second semiconductor structure includes a flange on an edge of the non-transferred portion of the epitaxial layer, the flange corresponding to a periphery of the transferred epitaxial portion, and wherein the flange is removed prior to the treating of the second semiconductor structure by a degassing heat treatment.

10. The method according to claim 9, wherein the degassing heat treatment is an annealing stage performed at a temperature that is greater than 700° C.

11. The method according to claim 9, further comprising cleaning a surface of the treated second semiconductor structure after the degassing heat treatment.

12. The method according to claim 11, wherein the cleaning is an RCA type cleaning.

13. The method according to claim 11, which further comprises forming an oxide layer on the surface of the treated second semiconductor structure after cleaning and eliminating the oxide layer to smooth the surface.

14. The method according to claim 13, wherein the oxide layer is eliminated by chemical etching.

15. The method according to claim 8, which further comprises providing an oxide layer on the epitaxial layer prior to bringing the donor wafer and receiving substrate into contact.

16. The method according to claim 8, which further comprises providing an overlayer upon the at least one epitaxial layer prior to bringing the donor wafer and receiving substrate into contact, wherein the overlayer has a mesh parameter that is essentially the same as that of the adjacent epitaxial layer.

17. The method according to claim 1, wherein the support substrate is an Si substrate, and the hetero-epitaxial layer comprises a buffer layer of SiGe, and an epitaxial layer of relaxed SiGe, and wherein the buffer layer is formed by epitaxial growth on the support substrate and has a Ge content which progressively increases from an interface with the support substrate.

18. The method according to claim 17, which further comprises providing an overlayer upon the at least one epitaxial layer prior to bringing the donor wafer and receiving substrate into contact, wherein the overlayer comprises a strained Si layer or a first layer of relaxed SiGe and a second layer of strained Si on the first layer.

19. The method according to claim 17, which further comprises providing an oxide layer on the epitaxial layer prior to bringing the donor wafer and receiving substrate into contact, wherein the oxide layer is silicon dioxide.

20. A method for producing two or more semiconductor structures using a single donor wafer, the method comprising the steps of:
providing a donor wafer comprising a support substrate, and a hetero-epitaxial layer,
comprising a buffer layer having a mesh parameter that is different from that of the support substrate, and at least one epitaxial layer of semiconductor material on the buffer layer;
wherein the thickness of one epitaxial layer is sufficient to provide at least two portions for transfer;
transferring a portion of the at least one epitaxial layer to a receiver wafer to form a first semiconductor structure which comprises the receiver wafer and a semiconductor layer of the at least one epitaxial layer portion on the receiver wafer and second semiconductor structure which comprises the support substrate, the buffer layer and the remaining, non-transferred portion of the epitaxial layer, wherein the non-transferred portion has a thickness sufficient to provide at least a second transfer portion;
treating the second semiconductor structure by removing at least part of the remaining, non-transferred portion of the same epitaxial layer without removing the buffer layer to form a treated semiconductor structure having a surface that is sufficiently smooth for growth of at least one further epitaxial layer thereon; and
recycling the treated semiconductor structure for transfer of at least a second portion of the same epitaxial layer.
